(19) United States
(12) Patent Application Publication
(10) Pub. No.: US 2024/0332322 A1
(43) Pub. Date: Oct. 3, 2024

(54) INDUCTORLESS CIRCUITS FOR CURRENT-VOLTAGE CONTROL AND REGULATION IN GLASS CORE

(71) Applicant: Intel Corporation, Santa Clara, CA (US)

(72) Inventors: Srinivasan Raman, Chandler, AZ (US); Brandon C. Marin, Gilbert, AZ (US); Srinivas Venkata Ramanuja Pietambaram, Chandler, AZ (US); Gang Duan, Chandler, AZ (US); Suddhasattwa Nad, Chandler, AZ (US); Kripa Chauhan, Gilbert, AZ (US)

(73) Assignee: Intel Corporation, Santa Clara, CA (US)

(21) Appl. No.: 18/129,407

(22) Filed: Mar. 31, 2023

(51) Int. Cl. H01L 27/13; H01L 21/84; H01L 23/482; H01L 25/16; H01L 25/18; H01L 29/66; H01L 29/772

(52) U.S. Cl. CPC H01L 27/13; H01L 21/84; H01L 23/482; H01L 25/16; H01L 25/18; H01L 29/66409; H01L 29/772

(57) ABSTRACT

An electronic device and associated methods are disclosed. In one example, the electronic device includes an electronic package substrate including a glass core layer and a regulator circuit. A first portion of the circuit components of the regulator circuit is embedded in the glass core layer and a second portion of the circuit components of the regulator circuit is formed on a surface of the glass core layer.

### TECHNICAL FIELD

Embodiments pertain to packaging of electronic systems. Some embodiments relate to techniques of embedding electronic devices in a glass layer of a substrate of an electronic package.

### BACKGROUND

Electronic systems continue to increase in complexity. Electronic systems often include integrated circuits (ICs) that are interconnected and packaged as a subassembly. It is desired to integrate multiple types of IC dies into a single package to create an efficient system in a package. As packaged electronic systems become larger due to adding more IC dies, the area form factor (e.g., X-Y dimensions) of the packages becomes larger. However, it is desired to keep the size of electronic packages small.

### BRIEF DESCRIPTION OF THE DRAWINGS

FIG. 1 is a cross section view of an example of portions an electronic device in accordance with some example embodiments.

FIGS. 2A and 2B illustrate a cross section view of a portion of an example of a regulator circuit embedded in a glass core layer in accordance with some example embodiments.

FIG. 3 is another cross section view of an example of a regulator circuit embedded in a glass core layer in accordance with some example embodiments.

FIG. 4 is a top view of an example of a regulator circuit embedded in a glass core layer in accordance with some example embodiments.

FIG. 5 is a top view of another example of a regulator circuit embedded in a glass core layer in accordance with some example embodiments.

FIGS. 6A-6F show a flow diagram of a method of manufacture of a fin-type linear current regulator circuit in accordance with some example embodiments.

FIGS. 7A-7G show a flow diagram of a method of manufacture of a transistor in a glass core layer in accordance with some example embodiments.

FIGS. 8A and 8B illustrate a cross section view of another example of a regulator circuit embedded in a glass core layer in accordance with some example embodiments.

FIGS. 9A-9D show a flow diagram of a method of manufacture of a resistive segment embedded in a glass core layer in accordance with some example embodiments.

FIG. 10 shows a system that may incorporate regulator circuits embedded in a glass core layer in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

To meet the demand for increased functional complexity in smaller devices, manufacturers integrate multiple integrated circuit (IC) dies in a single electronic package to create an efficient electronic system in a package. The trend to package multiple IC dies into one electronic system can lead to needing large package sizes to fit all the dies. The current package technologies for electronic packaging are limited in the area form factor (e.g., X-Y dimension) that can be achieved due to warping.

The susceptibility to warping limits the number of IC dies that can be included in multi-dies assemblies and limits the size of an electronic package. Package warpage is the deviation from flatness caused by internal stress of the electronic package. Warpage can lead to different solder joint geometries between the center and the edge of the interposer area, which can reduce the reliability. In addition, warpage can lead to solder balls bridging and interconnect opens or shorts between the solder balls which reduces the assembly yield. To meet the demand for increased functional complexity in electronic devices, semiconductor substrate packaging can include a stiffening layer such as glass core layer to address warping.

Electronic systems can include regulator circuits that regulate one or both of voltage and current. The transistors used for the regulator circuits are typically placed in an IC and passive components used in the regulator circuits such as resistors and capacitors are placed externally on package surfaces. To reduce the size of electronic systems, the transistors and passive components can be formed in and on the glass core layer. Both analog and digital circuits can be integrated into the glass core layer to add circuit functionalities to the electronic package. Moving the regulator circuit components to the glass core layer can simplify routing because the components can be moved close to each other in the glass core layer instead of some of the components being included in an IC die. Additionally, the circuits can be designed to eliminate the bulkiest components such as inductors.

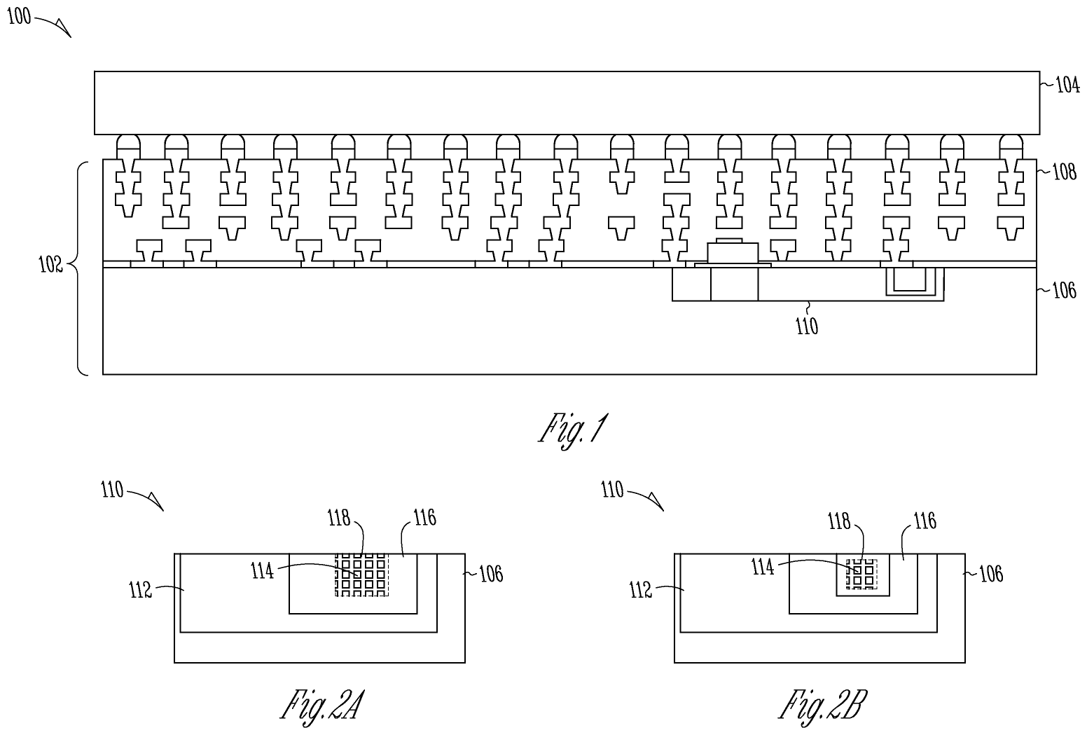

FIG. 1 illustrates a cross section view of an example of portions an electronic device 100 that includes an electronic package substrate 102 and an integrated circuit (IC) die 104 mounted on the top surface of the substrate 102. The IC die 104 can be a CPU die for example. The substrate 102 includes a glass core layer 106 that serves as a stiffening material for the substrate 102. The substrate 102 may also include a redistribution layer (RDL) 108 on the top surface of the glass core layer 106 and the IC die 104 is attached to the RDL 108. The RDL 108 can include sublayers of conductive traces formed in an organic material. The glass core layer 106 includes a regulator circuit 110 embedded in the glass core layer 106. The RDL 108 can provide electrical continuity between the regulator circuit 110 and the IC die 104.

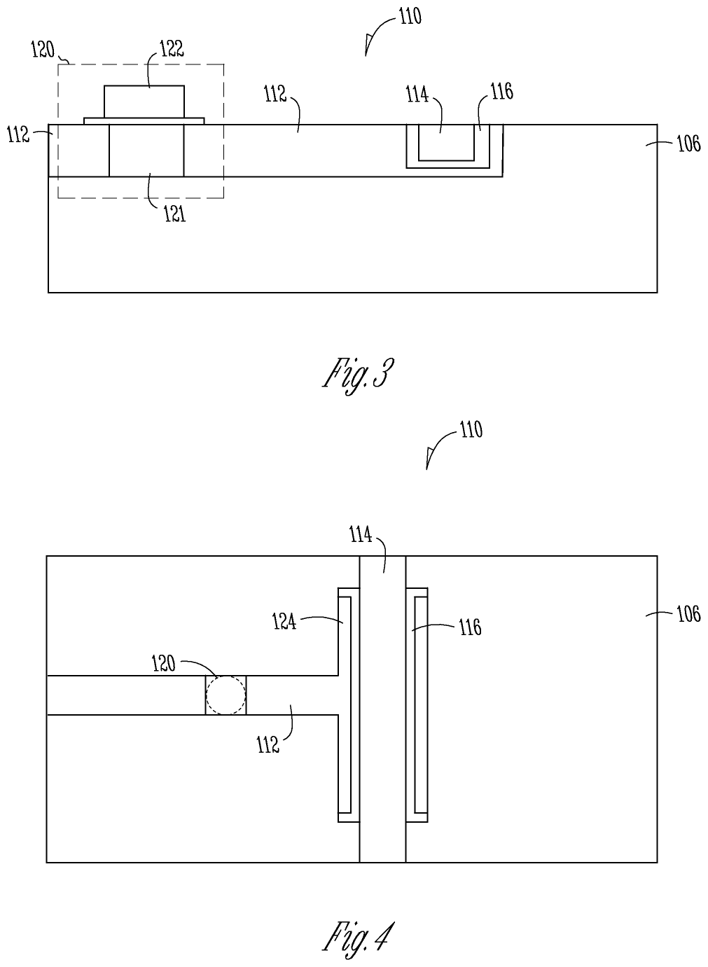

FIGS. 2A and 2B illustrate a cross section view of a portion of the regulator circuit 110 embedded in the glass core layer 106. The regulator circuit 110 is a fin-type linear current regulator circuit. The circuit includes a gate trace 112, power delivery trace 114, and a dielectric layer 116 between the gate trace 112 and power delivery trace 114. In some examples, the gate trace 112 is formed on the surface of the glass core layer 106.

The current passing through the regulator circuit 110 is regulated by a voltage applied to the gate trace 112. In FIG. 2A, zero volts (OV) is applied to the gate traces and zero volts is present across the dielectric. The dashed-line box 118 shows the cross section area of the power delivery trace 114 available to pass current. The dielectric material of the dielectric layer 116 is a fin-type current control dielectric. In FIG. 2B, a negative voltage (−V) applied to the gate trace 112 places a bias voltage across the dielectric that creates a depletion region of charge carriers in the power delivery trace. The result is that the cross section area of the power delivery trace 114 available to pass current is reduced as shown by the decrease in size of the dashed-line box 118 in FIG. 2B. The voltage applied to the gate trace 112 “throttles” the current through the power delivery trace 114.

FIG. 3 illustrates another cross section view of the regulator circuit 110. FIG. 3 shows that the gate trace 112 is a switched connection. Switch circuit 120 may be a field effect transistor (FET) formed partly in the glass core layer and partly on the surface of the glass core layer 106. The switch circuit 120 includes a semiconductor layer 121 within the glass core layer 106 and a control terminal 122 on top of the glass core layer 106. The control terminal 122 of the switch circuit 120 can be connected to an enable trace on the surface of the glass core layer 106 or a conductive trace of the RDL 108 in FIG. 1. Activating the switch circuit 120 connects the gate trace 112 to other circuits of the glass core layer 106 or the RDL 108.

FIG. 4 is a top view of the regulator circuit 110 showing the gate trace 112, power delivery trace 114, dielectric layer 116, and switch circuit 120. FIG. 4 also shows a conductive control fin 124 around the current control dielectric 116. The regulator circuit 110 in the examples of FIGS. 3 and 4 provides linear current regulation without bulky circuit components (e.g., capacitors, inductors, etc.) on the surface of the package substrate and without routing to circuit components included in a separate IC die. This makes the electronic substrate package 102 thinner.

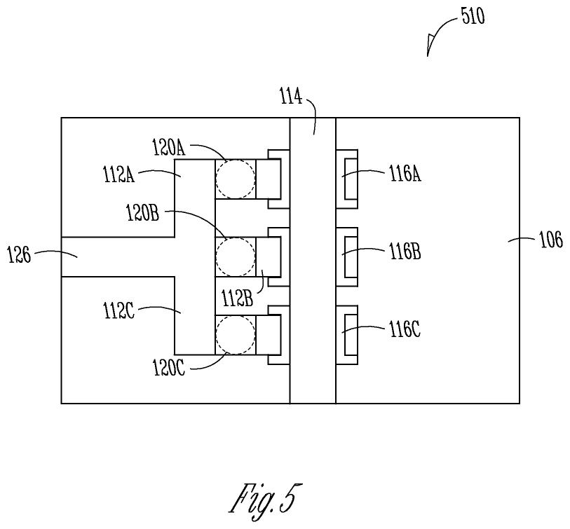

FIG. 5 is a top of another example of a fin-type linear regulator circuit 510. The regulator circuit 510 includes multiple gate traces 112A-112C and a power delivery trace 114. The gate traces 112A-112C intersect the power delivery trace 114 at multiple intersecting segments. Each of the segments includes a dielectric layer 116A-116C between the corresponding gate trace 112A-112C and the power delivery trace 114. The gate traces 112A-112C throttle the current at multiple points of the power delivery trace 114. Each gate trace 112A-112C may include a switch circuit 120A-120C, or the regulator circuit 510 can include one switch circuit on the main trace 126 before the main trace separates into the multiple gate traces 112A-112C.

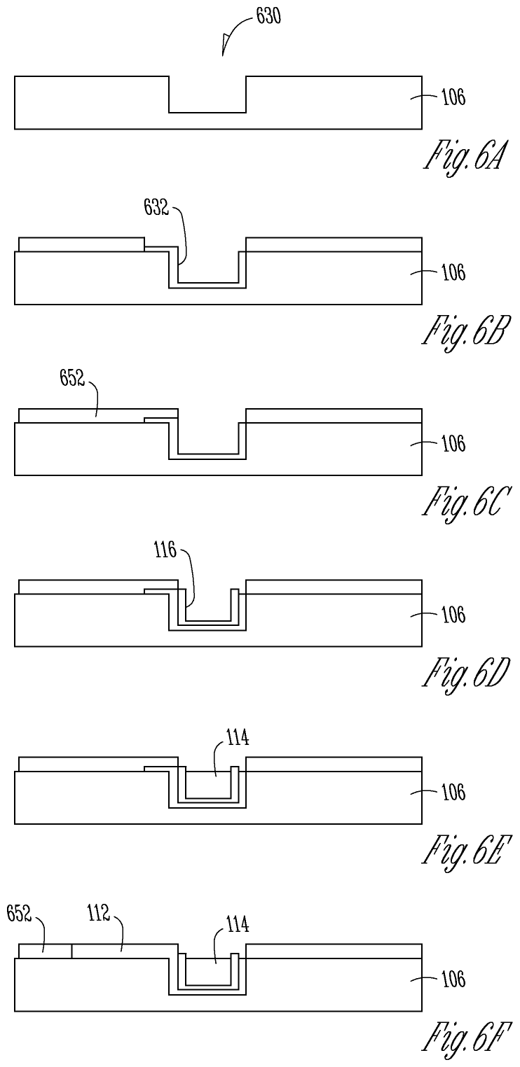

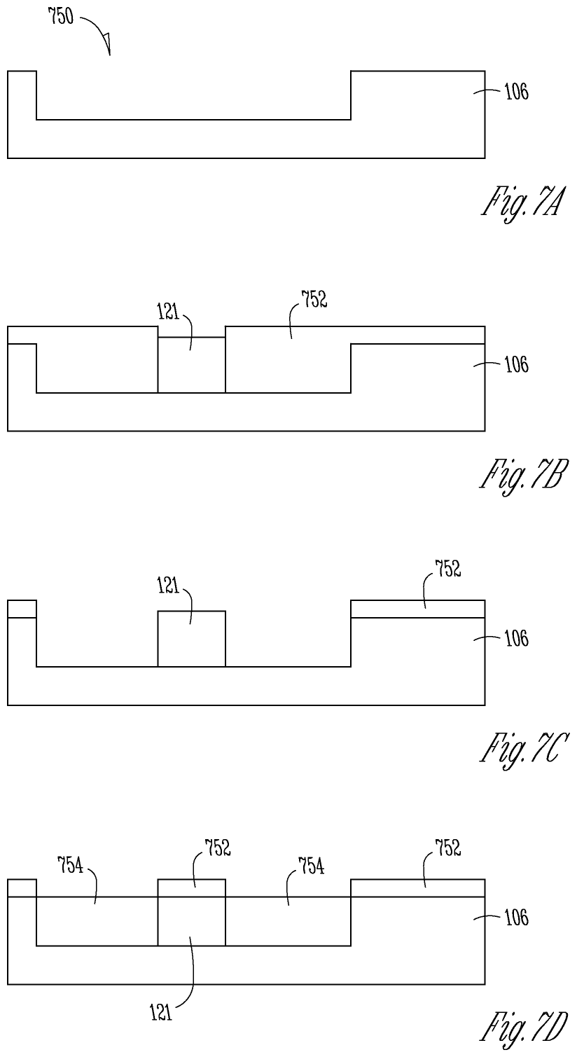

FIGS. 6A-6F show a flow diagram of a method of manufacture of a fin-type linear current regulator circuit in a glass core layer of an electronic package substrate (such as the substrate 102 of FIG. 1). In FIG. 6A, a cavity 630 is formed in a glass layer that will be the glass core layer 106 of the substrate. The glass layer may include a silicate-based glass (e.g., lithium-silicate, borosilicate, aluminum silicate, etc.). In variations, the glass layer includes a lower quality glass (e.g., glass made with soda lime), or a higher quality glass (e.g., quartz glass made with fused silica). In some examples, the glass layer includes at least 70% silica. The cavity 630 can be formed in the glass layer by infrared lasering and etching.

In FIG. 6B, the cavity is coated with a metal 632 (e.g., copper) to form a conductive cavity. The conductive cavity will be the conductive control fin of the linear regulator circuit. The metal can be disposed in the cavity using a metal plating process or a metal deposition process.

In FIG. 6C additional lithography masking 652 is reformed to define the dielectric area of the linear regulator circuit, and in FIG. 6D, the conductive cavity is coated with a current control dielectric material to form a dielectric cavity for the dielectric layer 116. The dielectric material is a fin-type current control dielectric. In some examples, the dielectric material has a high dielectric constant (high K dielectric) such as hafnium silicate, zirconium silicate, hafnium dioxide, or zirconium dioxide. In some examples, the dielectric material is a thin-film capacitor material such as Strontium Titanium Oxide (STO), or Barium Strontium Titanate (BST). The high K dielectric can be deposited as a thin film using a thin film deposition process.

In FIG. 6E, the dielectric cavity is filled with a metal (e.g., copper) to form the power delivery trace 114. In FIG. 6F, the gate trace 112 is formed and connected to the power delivery trace 114. In the example of FIG. 6F, a portion of the lithography layer 652 is removed and the gate trace 112 is formed on surface of the glass core layer 106 where it connects to the power delivery trace. In some examples, a second cavity is formed in the glass core layer 106 and filled with the metal to form a gate trace 112 that is within the glass core layer 106 as in the example of FIG. 3. An RDL (e.g., RDL 108 in FIG. 1) can then be formed on the glass core layer 106 over the linear regulator circuit.

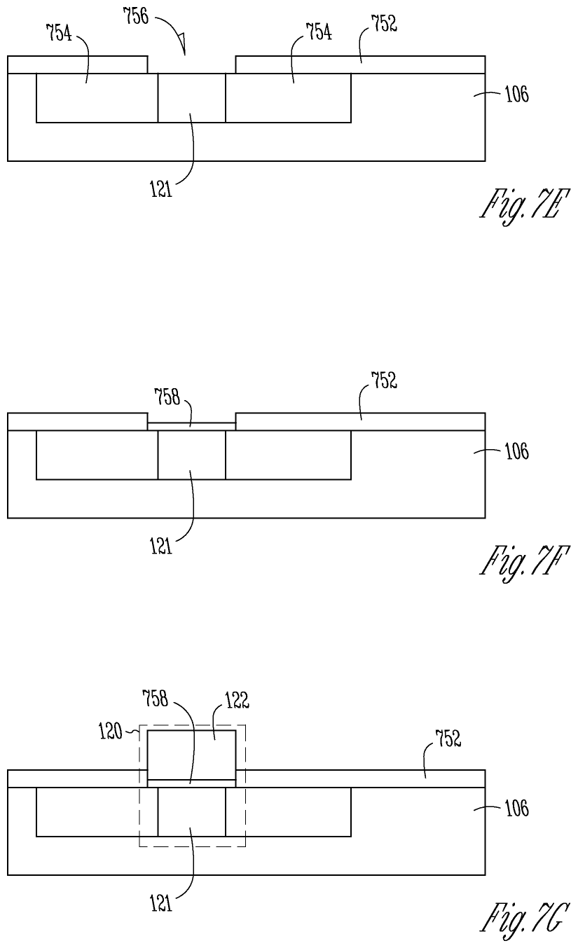

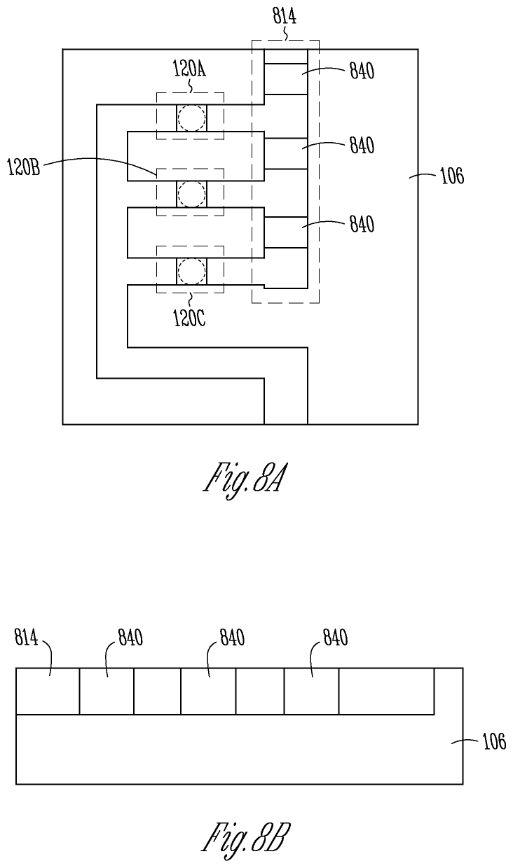

FIGS. 7A-7G show a flow diagram of a method of manufacture of an FET in a glass core layer in a glass core layer of an electronic package substrate (such as the FET 120 in FIG. 3). FIG. 7A shows a cross section view of a cavity 750 formed in a glass layer that will be the glass core layer 106 of the substrate. The cavity 750 can be formed by infrared laser and glass etching. The cavity 750 will be the power delivery trace region that may be used to connect to the gate trace 112 of a regulator circuit (such as the regulator circuit 110 of FIG. 1).

In FIG. 7B, the cavity 750 is filled lithography material 752 and a semiconductor material is disposed in the lithography material to form a semiconductor layer 121. The semiconductor layer 121 is included in the FET and may include one or both of a p-type semiconductor and an n-type semiconductor.

In FIG. 7C, the lithography material in the cavity is removed and reformed to define a region for disposing the metal (e.g., copper) for the power delivery trace. In FIG. 7D, the metal 754 is disposed in the cavities.

In FIG. 7E, the lithography material is removed and reformed to define a region 756 for disposing the dielectric material for the gate region of the FET. In FIG. 7F, the dielectric material is disposed on the semiconductor layer 121 to form a dielectric layer 758. In FIG. 7G, metal is disposed on the dielectric layer 758 to form the control terminal 122 of the FET. The FET 120 can be partly formed in the glass core layer 106 with the control terminal 122 above the top surface of the glass core layer 106.

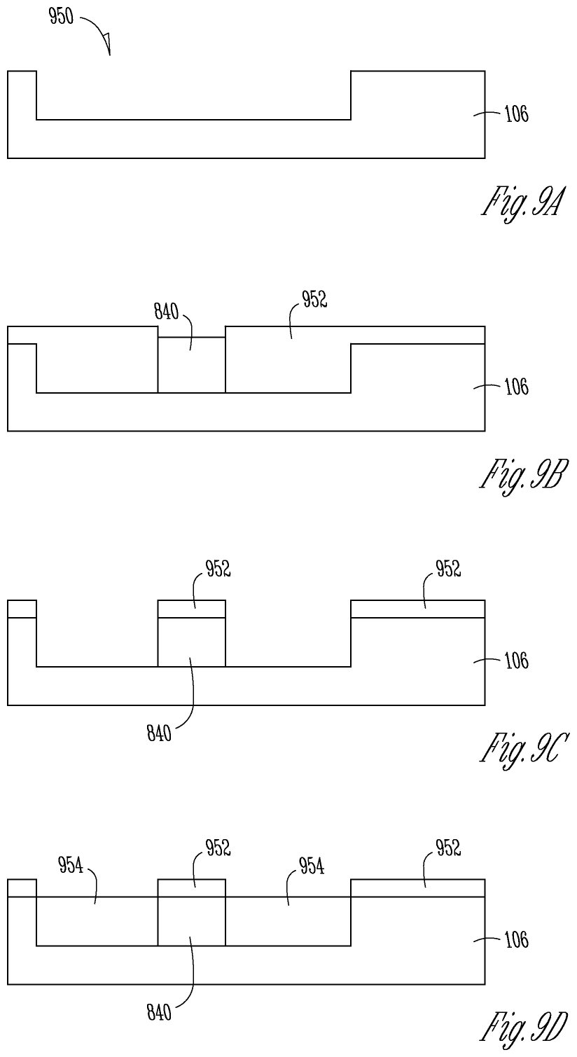

FIGS. 8A-8B illustrate another example of a regulator circuit that can be embedded in the glass core layer 106. The circuit is a digital potentiometer circuit 810 that provides a changeable resistance between terminals of the circuit. FIG. 8A is a top view of the potentiometer circuit 810 and FIG. 8B is a cross section view of a portion of the potentiometer in potentiometer circuit 810. The circuit includes a power trace 814 that includes a conductive trace formed in the glass core layer 106. The power trace also includes multiple resistive segments 840 formed in the glass core layer 106. Each resistive segment is connectable into the power trace 814 by a switch circuit 120A-120C. The switch circuits 120A-120C can be FETs formed on the surface of the glass core layer 106. The potentiometer circuit 810 can include enable traces (not shown) to activate the switch circuits 120A-120C. The enable traces may be formed on the surface of the glass core layer 106 or the enable traces can be included in the RDL 108 of FIG. 1.

FIG. 8B is a cross section view of the power trace 814. The resistive segments 840 can be metal-alloy resistors embedded in the glass core layer 106. Activating switch circuit 120A includes one resistor in the power trace 814, activating switch circuit 120A includes two resistors in the power trace 814, and activating switch circuit 120C includes three resistors in the power trace 814. Changing the resistance between the terminals of the potentiometer circuit 810 changes the voltage between the terminals for a specified current applied to the power trace 814. The potentiometer circuit 810 provides voltage regulation without resistors placed on the surface of the package substrate and without routing to circuit components included in a separate IC die, thereby making the electronic substrate package thinner.

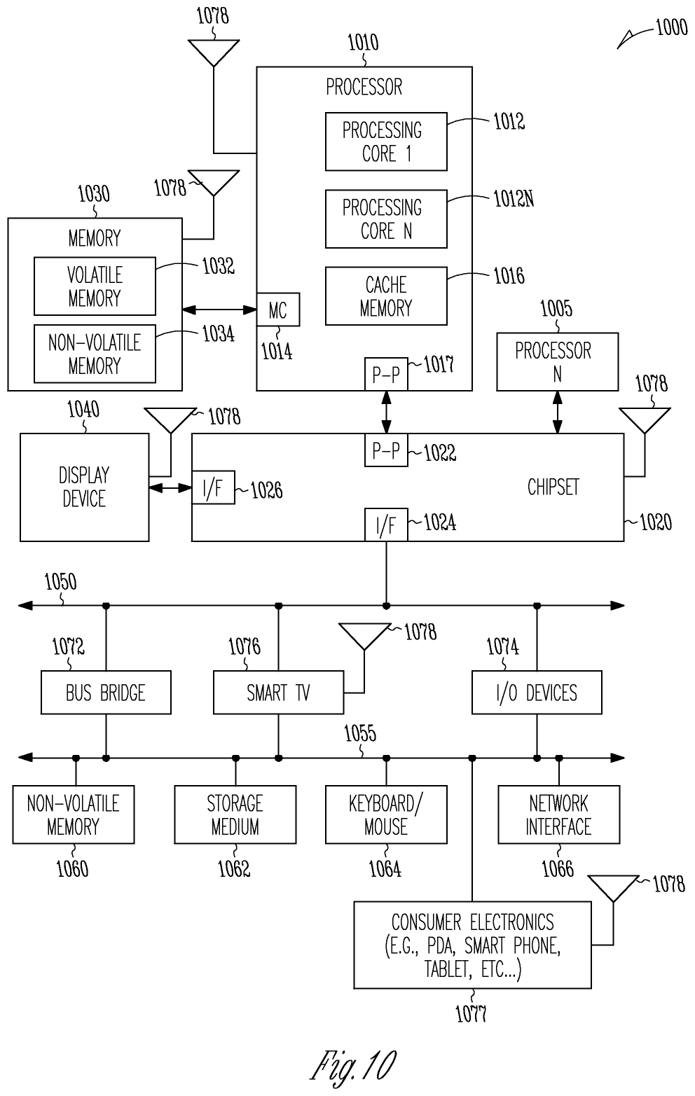

FIGS. 9A-9D show a flow diagram of a method of manufacture of a resistive segment (e.g., a resistive segment 840 in FIG. 8) embedded in a glass core layer. FIG. 9A shows a side view of a cavity 950 formed in a glass layer that will be the glass core layer 106 of the substrate. The cavity 950 can be formed by infrared laser and glass etching. The cavity 950 may be a one or more sections of a power trace region of a potentiometer circuit (e.g., the potentiometer circuit 810 in FIG. 8).

In FIG. 9B, the cavity 950 lithography material 952 is disposed in the cavity 950 and a resistive material is disposed in the lithography material 952 to form a resistive segment 840. In FIG. 9C, the lithography material 952 in the cavity is removed and reformed to define a region for disposing the metal (e.g., copper) for the power trace 814. In FIG. 9D, the metal 954 is disposed in the cavities.

FIG. 10 illustrates a system level diagram, depicting an example of an electronic device (e.g., system) that may include the glass core embedded regulator circuits described above. In one embodiment, system 1000 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1000 includes a system on a chip (SOC) system.

In one embodiment, processor 1010 has one or more processor cores 1012 and 1012N, where 1012N represents the Nth processor core inside processor 1010 where N is a positive integer. In one embodiment, system 1000 includes multiple processors including 1010 and 1005, where processor 1005 has logic similar or identical to the logic of processor 1010. In some embodiments, processing core 1012 includes, but is not limited to, pre-fetch logic to fetch instructions, decode logic to decode the instructions, execution logic to execute instructions and the like. In some embodiments, processor 1010 has a cache memory 1016 to cache instructions and/or data for system 1000. Cache memory 1016 may be organized into a hierarchal structure including one or more levels of cache memory.

In some embodiments, processor 1010 includes a memory controller 1014, which is operable to perform functions that enable the processor 1010 to access and communicate with memory 1030 that includes a volatile memory 1032 and/or a non-volatile memory 1034. In some embodiments, processor 1010 is coupled with memory 1030 and chipset 1020. Processor 1010 may also be coupled to a wireless antenna 1078 to communicate with any device configured to transmit and/or receive wireless signals. In one embodiment, an interface for wireless antenna 1078 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1032 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1034 includes, but is not limited to, flash memory, phase change memory (PCM), read-only memory (ROM), electrically erasable programmable read-only memory (EEPROM), or any other type of non-volatile memory device. A regulated voltage or current can be provided to one or more of the logic, processors, and memory using any of the glass core embedded regulator circuits described herein.

Memory 1030 stores information and instructions to be executed by processor 1010. In one embodiment, memory 1030 may also store temporary variables or other intermediate information while processor 1010 is executing instructions. In the illustrated embodiment, chipset 1020 connects with processor 1010 via Point-to-Point (PtP or P-P) interfaces 1017 and 1022. Chipset 1020 enables processor 1010 to connect to other elements in system 1000. In some embodiments of the example system, interfaces 1017 and 1022 operate in accordance with a PtP communication protocol such as the Intel® QuickPath Interconnect (QPI) or the like. In other embodiments, a different interconnect may be used.

In some embodiments, chipset 1020 is operable to communicate with processor 1010, 1005N, display device 1040, and other devices, including a bus bridge 1072, a smart TV 1076, I/O devices 1074, nonvolatile memory 1060, a storage medium (such as one or more mass storage devices) 1062, a keyboard/mouse 1064, a network interface 1066, and various forms of consumer electronics 1077 (such as a PDA, smart phone, tablet etc.), etc. In one embodiment, chipset 1020 couples with these devices through an interface 1024. Chipset 1020 may also be coupled to a wireless antenna 1078 to communicate with any device configured to transmit and/or receive wireless signals.

Chipset 1020 connects to display device 1040 via interface 1026. Display 1040 may be, for example, a liquid crystal display (LCD), a light emitting diode (LED) array, an organic light emitting diode (OLED) array, or any other form of visual display device. In some embodiments of the example system, processor 1010 and chipset 1020 are merged into a single SOC. In addition, chipset 1020 connects to one or more buses 1050 and 1055 that interconnect various system elements, such as I/O devices 1074, nonvolatile memory 1060, storage medium 1062, a keyboard/mouse 1064, and network interface 1066. Buses 1050 and 1055 may be interconnected together via a bus bridge 1072.

In one embodiment, mass storage device 1062 includes, but is not limited to, a solid state drive, a hard disk drive, a universal serial bus flash memory drive, or any other form of computer data storage medium. In one embodiment, network interface 1066 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 10 are depicted as separate blocks within the system 1000, the functions performed by some of these blocks may be integrated within a single semiconductor circuit or may be implemented using two or more separate integrated circuits. For example, although cache memory 1016 is depicted as a separate block within processor 1010, cache memory 1016 (or selected aspects of 1016) can be incorporated into processor core 1012.

To better illustrate the method and apparatuses disclosed herein, a non-limiting list of embodiments is provided here:

Example 1 includes subject matter (such as an electronic device) comprising an electronic package substrate including a glass core layer and a regulator circuit that includes circuit components. A first portion of the circuit components of the regulator circuit is embedded in the glass core layer and a second portion of the circuit components of the regulator circuit is formed on a surface of the glass core layer.

In Example 2, the subject matter of Example 1, optionally includes a regulator circuit that includes a linear current regulator circuit.

In Example 3, the subject matter of Example 2 optionally includes a linear current regulator circuit that includes at least one gate trace that is a conductive trace formed in the glass core layer; a power delivery trace that is another conductive trace formed in the glass core layer; a current control dielectric formed between the at least one gate trace and the power delivery trace; and at least one switch circuit operatively connected to the at least one gate trace and formed on a surface of the glass core layer.

In Example 4, the subject matter of Example 3 optionally includes a switch circuit includes a field effect transistor (FET) formed on surface of the glass core layer.

In Example 5, the subject matter of one or both of Examples 3 and 4 optionally include multiple gate traces that intersect the power delivery trace at multiple intersecting segments; a current control dielectric is disposed between the gate traces and the power delivery trace at the multiple intersecting segments; and multiple switch circuits connected to the multiple gate traces.

In Example 6, the subject matter of one or any combination of Examples 1-5 optionally includes a regulator circuit includes a potentiometer circuit.

In Example 7, the subject matter of Example 6 optionally includes a potentiometer circuit that includes a power trace including a conductive trace formed in the glass core layer; multiple resistive segments embedded in the glass core layer and connectable to the power trace; and at least one switch circuit operatively connected to the power trace and formed on a surface of the glass core layer. Activating the at least one switch circuit connects a resistive segment to the power trace.

In Example 8, the subject matter of Example 7 optionally includes at least one switch circuit that includes a field effect transistor (FET) formed on surface of the glass core layer.

In Example 9, the subject matter of one or both of Examples 7 and 8 optionally includes each resistive segment including a resistor connectable to the power trace and a switch circuit to connect the resistor to the power trace.

Example 10 includes subject matter (such as an electronic device) or can optionally be combined with one or any combination of Examples 1-9 to include such subject matter comprising an electronic substrate. The electronic substrate includes a glass core layer, a redistribution layer (RDL), and a regulator circuit. At least a portion of circuit components of the regulator circuit is embedded in the glass core layer. The RDL is formed on the glass core layer and regulator circuit, and the RDL includes at one sublayer including a first conductive trace contacting the regulator circuit.

In Example 11, the subject matter of Example 10 optionally includes an integrated circuit (IC) attached to the RDL, wherein the RDL provides electrical continuity between the IC and the regulator circuit.

In Example 12, the subject matter of one or both of Example 10 and 11 optionally includes a regulator circuit includes a linear current regulator circuit.

In Example 13, the subject matter of Example 12 optionally includes a linear current regulator circuit that includes a second conductive trace that is a gate trace formed in the glass core layer; a third conductive trace that is a power delivery trace formed in the glass core layer; a current control dielectric formed between the gate trace and the power delivery trace; and a switch circuit operatively connected to the gate trace and formed on a surface of the glass core layer. The first conductive trace of the RDL contacts a control input of the switch circuit.

In Example 14, the subject matter of Example 13 optionally includes the switch circuit including a field effect transistor (FET) formed on surface of the glass core layer.

In Example 15, the subject matter of one or any combination of Examples 10-14 optionally includes a regulator circuit including a potentiometer circuit.

In Example 16, the subject matter of Example 15 optionally includes a potentiometer circuit including a second conductive trace that is a power trace formed in the glass core layer; at least one resistor embedded in the glass core layer; and at least one switch circuit operatively connected to the power trace and formed on a surface of the glass core layer wherein the first conductive trace of the RDL contacts a control input of the switch circuit.

In Example 17, the subject matter of Example 16 optionally includes a switch circuit that includes a field effect transistor (FET), and at least a portion of the FET is formed in the glass core layer.

Example 18 includes subject matter (such as a method of forming an electronic device) or can optionally be combined with one or any combination of Examples 1-17 to include such subject matter, comprising forming a cavity in a glass core layer; coating the cavity with a metal to form a conductive cavity that is a conductive control fin in the glass core layer; coating the conductive cavity with a current control dielectric material to form a dielectric cavity; filling the dielectric cavity with the metal to form a power delivery trace; and forming a gate trace connected to the power delivery trace.

In Example 19, the subject matter of Example 18 optionally includes forming the gate trace in the cavity of the glass core layer.

In Example 20, the subject matter of Example 18 optionally includes forming the gate trace on a surface of the glass core layer.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic device, comprising:
an electronic package substrate including a glass core layer; and
a regulator circuit, wherein a first portion of circuit components of the regulator circuit is embedded in the glass core layer and a second portion of the circuit components of the regulator circuit is formed on a surface of the glass core layer.

2. The electronic device of claim 1, wherein the regulator circuit includes a linear current regulator circuit.

3. The electronic device of claim 2, wherein the linear current regulator circuit includes:
at least one gate trace that is a conductive trace formed in the glass core layer;
a power delivery trace that is another conductive trace formed in the glass core layer;
a current control dielectric formed between the at least one gate trace and the power delivery trace; and
at least one switch circuit operatively connected to the at least one gate trace and formed on a surface of the glass core layer.

4. The electronic device of claim 3, wherein the switch circuit includes a field effect transistor (FET) formed on surface of the glass core layer.

5. The electronic device of claim 3,
wherein the at least one gate trace includes multiple gate traces that intersect the power delivery trace at multiple intersecting segments;
wherein the current control dielectric is disposed between the gate traces and the power delivery trace at the multiple intersecting segments; and
wherein the at least one switch circuit includes multiple switch circuits connected to the multiple gate traces.

6. The electronic device of claim 1, wherein the regulator circuit includes:
a first gate trace, a second gate trace, and a third gate trace, wherein the first, second, and third gate traces each include a conductive trace that includes a conductive material formed in the glass core layer;
another conductive trace formed in the glass core layer;
a current control dielectric formed between the first, second, and third gate traces and the other conductive trace; and
a first switch circuit, a second switch circuit, and a third switch circuit, wherein each switch circuit is formed on a surface of the glass core layer and operatively connected to one of the first gate trace, the second gate trace, or the third gate trace.

7. The electronic device of claim 1, wherein the regulator circuit includes a potentiometer circuit.

8. The electronic device of claim 7, wherein the potentiometer circuit includes:
a power trace including a conductive trace formed in the glass core layer;
multiple resistive segments embedded in the glass core layer and connectable to the power trace; and
at least one switch circuit operatively connected to the power trace and formed on a surface of the glass core layer, wherein activating the at least one switch circuit connects a resistive segment to the power trace.

9. The electronic device of claim 8, wherein the at least one switch circuit includes a field effect transistor (FET) formed on surface of the glass core layer.

10. The electronic device of claim 8, wherein each resistive segment includes a resistor connectable to the power trace and a switch circuit to connect the resistor to the power trace.

11. The electronic device of claim 1, wherein the regulator circuit includes:
a conductive trace including a conductive material formed in the glass core layer;
a first resistive segment, a second resistive segment, and a third resistive segment, each resistive segment including a resistive material embedded in the glass core layer and connectable to the conductive trace; and
at least one switch circuit operatively connected to the conductive trace and formed on a surface of the glass core layer, wherein activating the at least one switch circuit connects at least one of the first, second, or third resistive segments to the conductive trace.

12. The electronic device of claim 1, wherein glass of the glass core layer includes at seventy percent (70%) silica.

13. An electronic device, comprising:
an electronic substrate, including:
a glass core layer;
a regulator circuit, wherein at least a portion of circuit components of the regulator circuit is embedded in the glass core layer; and
a redistribution layer (RDL) formed on the glass core layer and regulator circuit, the RDL including at one sublayer including a first conductive trace contacting the regulator circuit.

14. The electronic device of claim 13, including an integrated circuit (IC) attached to the RDL, wherein the RDL provides electrical continuity between the IC and the regulator circuit.

15. The electronic device of claim 13, wherein the regulator circuit includes a linear current regulator circuit.

16. The electronic device of claim 15, wherein the linear current regulator circuit includes:
a second conductive trace that is a gate trace formed in the glass core layer;
a third conductive trace that is a power delivery trace formed in the glass core layer;
a current control dielectric formed between the gate trace and the power delivery trace; and
a switch circuit operatively connected to the gate trace and formed on a surface of the glass core layer, wherein the first conductive trace of the RDL contacts a control input of the switch circuit.

17. The electronic device of claim 16, wherein the switch circuit includes a field effect transistor (FET) formed on surface of the glass core layer.

18. The electronic device of claim 13, wherein the regulator circuit includes a potentiometer circuit.

19. The electronic device of claim 18, wherein the potentiometer circuit includes:
a second conductive trace that is a power trace formed in the glass core layer;
at least one resistor embedded in the glass core layer; and
at least one switch circuit operatively connected to the power trace and formed on a surface of the glass core layer wherein the first conductive trace of the RDL contacts a control input of the switch circuit.

20. The electronic device of claim 19, wherein the switch circuit includes a field effect transistor (FET), wherein at least a portion of the FET is included in the glass core layer.

21. A method of forming an electronic device, the method comprising:
forming a cavity in a glass core layer;
coating the cavity with a metal to form a conductive cavity that is a conductive control fin in the glass core layer;
coating the conductive cavity with a current control dielectric material to form a dielectric cavity;
filling the dielectric cavity with the metal to form a power delivery trace; and
forming a gate trace connected to the power delivery trace.

22. The method of claim 21, wherein forming the gate trace includes forming the gate trace in the cavity of the glass core layer.

23. The method of claim 21, wherein forming the gate trace includes forming the gate trace on a surface of the glass core layer.
